(19) United States
(12) Patent Application Publication
(10) Pub. No.: US 2013/0307044 A1
(43) Pub. Date: Nov. 21, 2013

(54) Selective Air Gap Isolation In Non-Volatile Memory

(71) Applicants: Hiroyuki Kinoshita, San Jose, CA (US); Ming Tian, Shanghai (CN); Daisuke Maekawa, Yokkaichi-city (JP); Naoki Watakabe, Yokkaichi-shi (JP); Seiji Shimabukuro, Yokkaichi (JP); Hiroaki Iuchi, Nagoya-city (JP); Hitomi Nakajima, Yokkaichi-shi (JP)

(72) Inventors: Hiroyuki Kinoshita, San Jose, CA (US); Ming Tian, Shanghai (CN); Daisuke Maekawa, Yokkaichi-city (JP); Naoki Watakabe, Yokkaichi-shi (JP); Seiji Shimabukuro, Yokkaichi (JP); Hiroaki Iuchi, Nagoya-city (JP); Hitomi Nakajima, Yokkaichi-shi (JP)

(21) Appl. No.: 13/472,337

(22) Filed: May 15, 2012

(51) Int. Cl. H01L 29/78; H01L 21/76

(52) U.S. Cl. 257/314; 438/421; 257/E21.573; 257/E29.255

(57) ABSTRACT

Air gap isolation in non-volatile memory arrays and related fabrication processes are provided. Electrical isolation between adjacent active areas of a substrate can be provided, at least in part, by bit line air gaps that are elongated in a column direction between the active areas. A blocking layer can be introduced to inhibit the formation of materials in the air gaps during subsequent process steps. The blocking layer may result in selective air gap formation or varying dimension of air gaps at cell areas relative to select gate areas in the memory. The blocking layer may result in a smaller vertical dimension for air gaps formed in the isolation regions at select gate areas relative to cell areas. The blocking layer may inhibit formation of air gaps at the select gate areas in other examples. Selective etching, implanting and different isolation materials may be used to selectively define air gaps.

### BACKGROUND OF THE INVENTION

1. Field of the Disclosure

Embodiments of the present disclosure are directed to high density semiconductor devices, such as non-volatile storage, and methods of forming the same.

2. Description of the Related Art

In most integrated circuit applications, the substrate area allocated to implement the various integrated circuit functions continues to decrease. Semiconductor memory devices, for example, and their fabrication processes are continuously evolving to meet demands for increases in the amount of data that can be stored in a given area of the silicon substrate. These demands seek to increase the storage capacity of a given size of memory card or other type of package and/or decrease their size.

Electrical Erasable Programmable Read Only Memory (EEPROM), including flash EEPROM, and Electronically Programmable Read Only Memory (EPROM) are among the most popular non-volatile semiconductor memories. One popular flash EEPROM architecture utilizes a NAND array having a large number of strings of memory cells connected through one or more select transistors between individual bit lines and common source lines. FIG. 1 is a top view showing a single NAND string and FIG. 2 is an equivalent circuit thereof. The NAND string depicted in FIGS. 1 and 2 includes four transistors 100, 102, 104 and 106 in series between a first select gate 120 and a second select gate 122. Select gate 120 connects the NAND string to a bit line via bit line contact 126. Select gate 122 connects the NAND string to a common source line via source line contact 128. Each of the transistors 100, 102, 104 and 106 is an individual storage element and includes a control gate and a floating gate. For example, transistor 100 includes control gate 100CG and floating gate 100FG, transistor 102 includes control gate 102CG and floating gate 102FG, transistor 104 includes control gate 104CG and floating gate 104FG, and transistor 106 includes control gate 106CG and floating gate 106FG. Control gate 100CG is connected to word line WL3, control gate 102CG is connected to word line WL2, control gate 104CG is connected to word line WL1, and control gate 106CG is connected to word line WL0.

Note that although FIGS. 1 and 2 show four memory cells in the NAND string, the use of four transistors is only provided as an example. A NAND string can have less than four memory cells or more than four memory cells. For example, some NAND strings will include eight memory cells, 16 memory cells, 32 memory cells, or more.

The charge storage elements of current flash EEPROM arrays are most commonly electrically conductive floating gates, typically formed from a doped polysilicon material. Another type of memory cell useful in flash EEPROM systems utilizes a non-conductive dielectric material in place of a conductive floating gate to form a charge storage element capable of storing charge in a non-volatile manner. Such a cell is described in an article by Chan et al., “A True Single-Transistor Oxide-Nitride-Oxide EEPROM Device,” IEEE Electron Device Letters, Vol. EDL-8, No. 3, March 1987, pp. 93-95. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. See also Nozaki et al., “A 1-Mb EEPROM with MONOS Memory Cell for Semiconductor Disk Application,” EEE Journal of Solid-State Circuits, Vol. 26, No. 4, April 1991, pp. 497-501, which describes a similar cell in a split-gate configuration where a doped polysilicon gate extends over a portion of the memory cell channel to form a separate select transistor.

Memory cells of typical non-volatile flash arrays are divided into discrete blocks of cells that are erased together. That is, the block contains the minimum number of cells that are separately erasable together as an erase unit, although more than one block may be erased in a single erase operation. Additionally, more recent memories may provide erasing in smaller units than blocks. Each block typically stores one or more pages of data, where a page includes the minimum number of cells that are simultaneously subjected to a data programming and read operation as the basic unit of programming and reading, although more than one page may be programmed or read in a single operation. Each page typically stores one or more sectors of data, the size of the sector being defined by the host system. An example is a sector of 512 bytes of user data, following a standard established with magnetic disk drives, plus some number of bytes of overhead information about the user data and/or the block in which it is stored.

As demands for higher densities in integrated circuit applications have increased, fabrication processes have evolved to reduce the minimum feature sizes of circuit elements such as the gate and channel regions of transistors. As the feature sizes have decreased, modifications to the traditional NAND memory array have been made to, among other things, decrease parasitic capacitances associated with small feature sizes.

### BRIEF DESCRIPTION OF THE DRAWINGS

FIG. 1 is a top view of a NAND string.

FIG. 2 is an equivalent circuit diagram of the NAND string depicted in FIG. 1.

FIG. 3 is a plan view of a portion of a NAND flash memory array.

FIG. 4 is an orthogonal cross-sectional view taken along line A-A of the portion of the flash memory array depicted in FIG. 3.

FIG. 5 is a three-dimensional drawing of a pair of four word line long portions of two NAND strings.

FIG. 6 is a three-dimension drawing showing a bit line or shallow trench isolation (STI) air gap as can be formed in one embodiment.

FIG. 7 is a cross-section view showing air gap formation with subsequent processing steps reducing the air gap size.

FIG. 8 is a cross-sectional view showing air gap formation using a blocking layer in accordance with one embodiment.

FIG. 9 is a flowchart describing a method of forming bit line and word line air gaps in accordance with one embodiment of the disclosure.

FIGS. 10A-10L are orthogonal cross-sectional and perspective views of a portion of a non-volatile memory array that may be fabricated according to the method of FIG. 9 in one embodiment.

FIG. 11 is a flowchart describing a method of forming bit line and word line air gaps in accordance with one embodiment of the disclosure.

FIGS. 12A-12C are cross-sectional views of a portion of a non-volatile memory array that may be fabricated according to the method of FIG. 11 in one embodiment.

FIG. 13 is a flowchart describing a method of forming bit line and word line air gaps in accordance with one embodiment of the disclosure.

FIGS. 14A-14F are orthogonal cross-sectional and perspective views of a portion of a non-volatile memory array that may be fabricated according to the method of FIG. 13 in one embodiment.

FIG. 15 depicts an example of the organization of a memory array in accordance with one embodiment.

FIG. 16 is a block diagram depicting an example of a memory system that can be fabricated or used to implement embodiments of the disclosed technology.

FIG. 17 is a block diagram depicting one embodiment of a sense block.

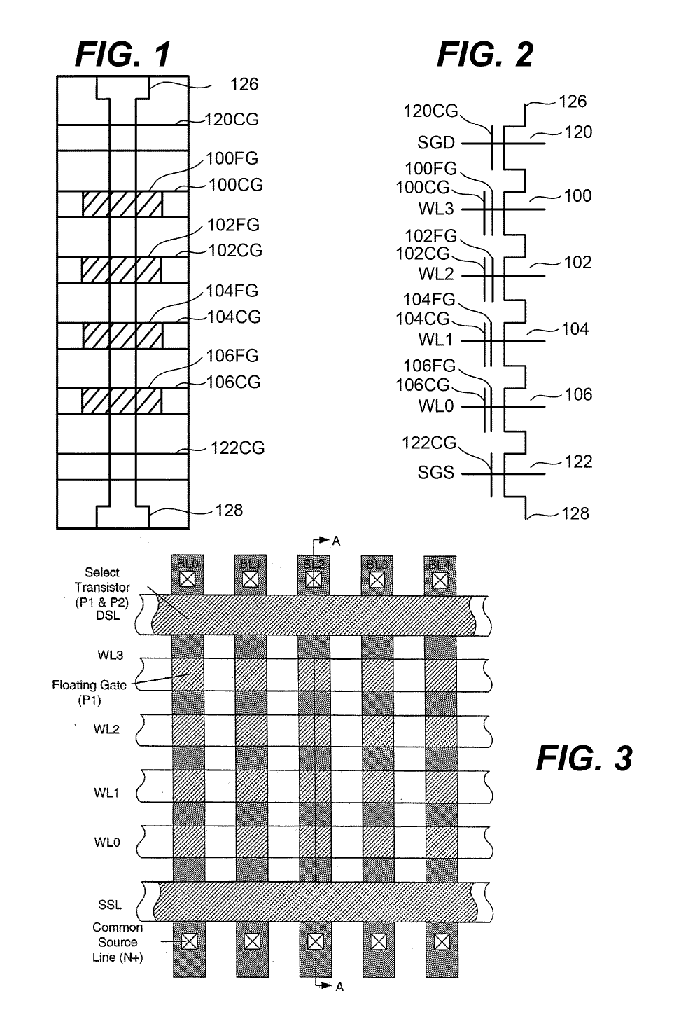

### DETAILED DESCRIPTION

Embodiments of the present disclosure are directed to high-density semiconductor memory, and more particularly to electrical isolation between discrete devices in non-volatile memory. Electrical isolation is provided, at least in part, by air gaps that are formed in the column (bit line) direction and/or air gaps that are formed in the row (word line) direction. Non-volatile memory arrays and related methods of fabrication are provided.

Air gaps formed in the column direction, referred to as bit line air gaps or shallow trench isolation (STI) air gaps, can provide electrical isolation between devices adjacent in the row direction. For example, adjacent columns of non-volatile storage elements, such as adjacent strings in a NAND type non-volatile memory, can be isolated using air gaps that are formed in the substrate between active areas underlying the adjacent columns. Although principally described with respect to NAND type non-volatile memory, it will be understood that the various air gaps described herein can be utilized in other arrays utilizing column and/or row arrangements for storage elements.

In one embodiment, air gaps are formed in the substrate between adjacent active areas of the substrate. The air gaps can be formed in pre-defined isolation regions etched in the substrate. A blocking layer can be introduced to inhibit the formation of materials in the air gaps during subsequent process steps. For example, liners and layers used in forming word line air gap capping layers may be inhibited or blocked from formation using a blocking layer selectively formed at a select gate area of the memory array. In one embodiment, the blocking layer results in smaller vertical dimension for air gaps formed in the isolation regions at the select gate areas relative to the cell areas. In another embodiment, the blocking layer inhibits formation of the air gaps at the select gate areas. Air gaps at the cell areas can then provide enhanced coupling and blocking benefits while traditional dielectric materials are used at the select gate areas without air gaps. This permits reduction in parasitic capacitance by introducing more uniform air isolation. Selective etching is used in one example to form a blocking layer from additional dielectric fill material at the select gate area. Selectively implanting of materials may be used in another example. In one embodiment, a different lower etch rate material is introduced at the select gate areas to inhibit air gap formation therein.

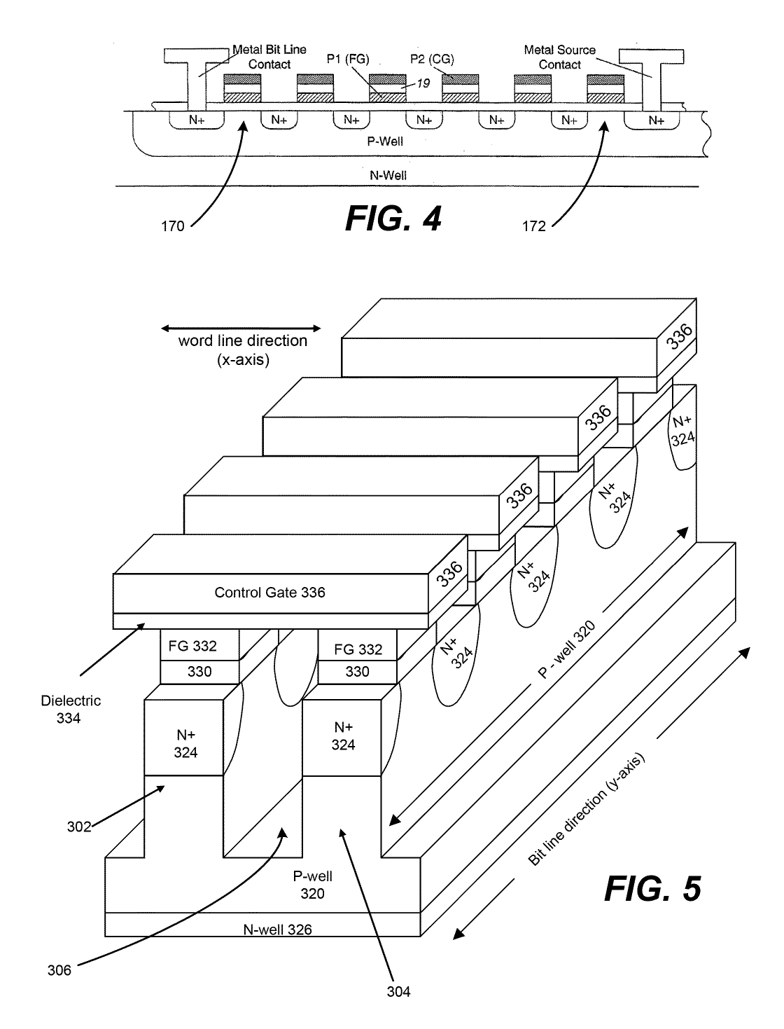

An example of a NAND type of memory array that can be fabricated in accordance with embodiments of the present disclosure is shown in plan view in FIG. 3. BL0-BL4 represent bit line connections to global vertical metal bit lines (not shown). Four floating gate memory cells are shown in each string by way of example. Typically, the individual strings include 16, 32 or more memory cells, forming a column of memory cells. Control gate (word) lines labeled WL0-WL3 extend across multiple strings over rows of floating gates, often in polysilicon. FIG. 4 is a cross-sectional view taken along line A-A of FIG. 3, depicting polysilicon layer P2 from which the control gate lines are formed. The control gate lines are typically formed over the floating gates as a self-aligned stack, and are capacitively coupled to the floating gates through an intermediate dielectric layer 162. The top and bottom of the string connect to a bit line and a common source line through select transistors (gates) 170 and 172, respectively. Gate 170 is controlled by selection line DSL and gate 172 is controlled by selection line SSL. The floating gate material (P1) can be shorted to the control gate for the select transistors to be used as the active gate. Capacitive coupling between the floating gate and the control gate allows the voltage of the floating gate to be raised by increasing the voltage on the control gate. An individual cell within a column is read and verified during programming by causing the remaining cells in the string to be turned on hard by placing a relatively high voltage on their respective word lines and by placing a relatively lower voltage on the one selected word line so that the current flowing through each string is primarily dependent only upon the level of charge stored in the addressed cell below the selected word line. That current typically is sensed for a large number of strings in parallel, in order to read charge level states along a row of floating gates in parallel. Examples of NAND memory cell array architectures and their operation as part of a memory system are found in U.S. Pat. Nos. 5,570,315, 5,774,397 and 6,046,935.

FIG. 5 is a three-dimensional block diagram of two exemplary NAND strings 302 and 304 that may be fabricated as part of a larger flash memory array. FIG. 5 depicts four memory cells on strings 302 and 304 as an example. FIG. 5 depicts N-well 326 below P-well 320. The bit line or y-direction runs along the NAND strings, and the word line or x-direction runs perpendicular to the NAND string or the bit line direction. The word line direction may also be referred to as the row direction and the bit line direction referred to as the column direction. The P-type substrate below N-well 336 is not shown in FIG. 5. In one embodiment, the control gates form the word lines. A continuous layer of conductive layer 336 can be formed which is consistent across a row in order to provide a common word line or control gate for each device on that word line. In such a case, this layer can be considered to form a control gate for each memory cell at the point where the layer overlaps a corresponding floating gate layer 332. In other embodiments, individual control gates can be formed and then interconnected by a separately formed word line.

When fabricating a NAND-type non-volatile memory system, including NAND strings as depicted in FIG. 5, electrical isolation is provided in the word line direction between adjacent strings. In the embodiment depicted in FIG. 5, NAND string 302 is separated from NAND string 304 by isolation area 306. Typically, an insulating material or dielectric is formed between adjacent NAND strings in this isolation area.

In accordance with embodiments of the present disclosure, air gaps are introduced in the column (bit line) and/or row (word line) direction to form electrical isolation between closely spaced components in the memory structure. Air gaps can decrease parasitic interferences between neighboring charge storage regions (e.g., floating gates), neighboring control gates and/or between neighboring floating and control gates. Air gaps can enhance coupling and boost ratios for programming non-volatile memory. Air gaps can include various material compositions and need not correspond to atmospheric air. For example, concentrations of elemental gases may vary in the air gap regions. An air gap is simply a void where no solid material is formed in the semiconductor structure.

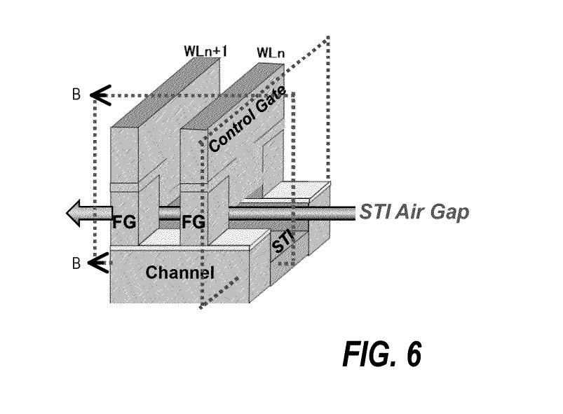

FIG. 6 depicts a portion of a non-volatile memory array having an air gap formed in a shallow trench isolation (STI) region extending in the column direction. The air gap extends in the column direction perpendicular to rows of memory cells including word lines Wln and WLn+1. In the vertical direction (perpendicular to the substrate surface), the air gap extends from above a dielectric fill material in the isolation region which defines a lower endpoint of the air gap. The air gap extends to the lower surface of the intermediate dielectric or IPD.

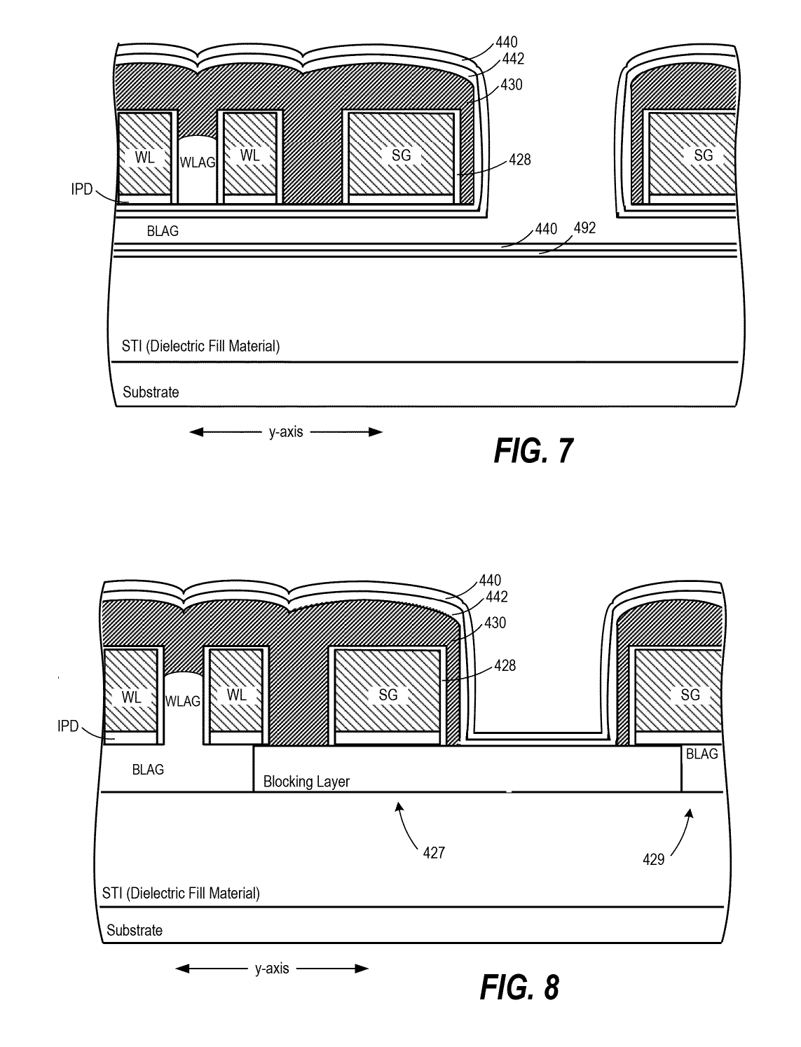

FIG. 7 is a cross-sectional view taken through line B-B of FIG. 6, showing further detail of the STI and air gap. A non-conformal dielectric oxide, e.g. oxide 430, has been formed to define word line air gaps WLAG in addition to the bit line air gaps BLAG formed in the STI areas. Additional liner layers 440 and 442 (e.g., oxides SiO2 or nitrides SiN) have also been formed before additional processing. As FIG. 7 illustrates, these materials, particularly the conformal liner layers 440 and 442 may enter the bit line air gap areas and/or word line air gaps and reduce the air gap dimension in the vertical direction. Subsequent wet chemicals used during etching and resist, for example, may also enter the air gap region. These types of materials may degrade performance and lead to a behavior more consistent with traditional dielectric fill materials than air-based regions.

FIG. 8 is a cross-sectional view like FIG. 7, further depicting a blocking layer in accordance with one embodiment that may be used to inhibit the formation of materials in later process steps within air gap regions. Various blocking layers, materials and fabrication processes may be used. A blocking layer may be formed under or close to the select gate areas but not in the cell areas in one example. In one example, the blocking layer completely prevents an air gap formation under the select gates or a portion of the select gates. In other examples, the blocking layer may result in air gaps at the select gate areas with a smaller vertical or other dimension than the air gaps at the cell area. See select gate area 427 and select gate area 429 for example.

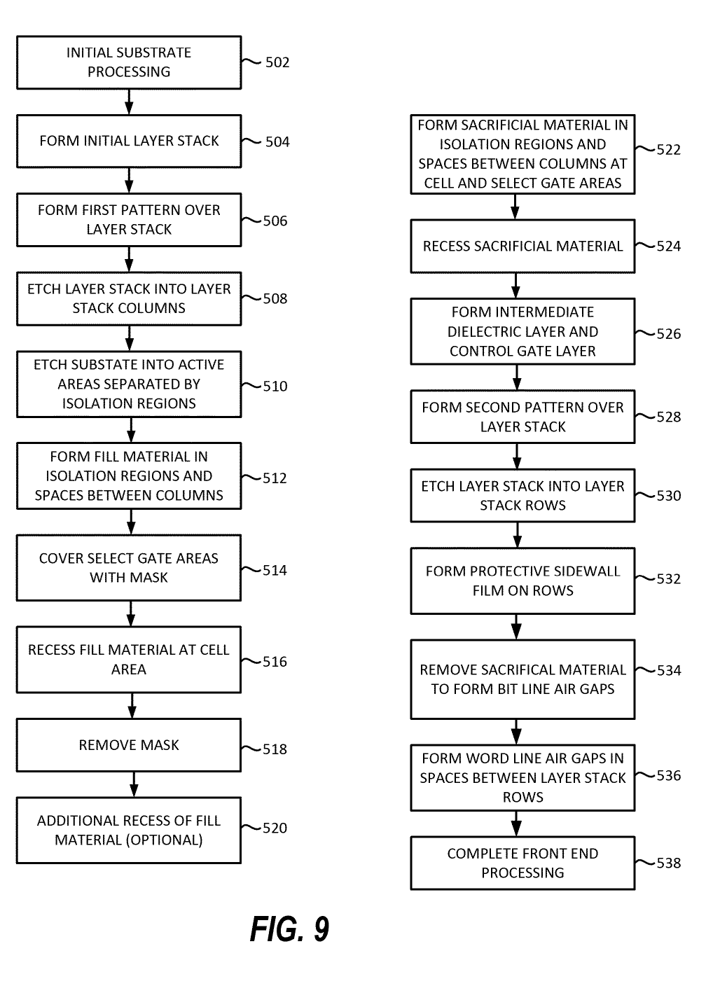

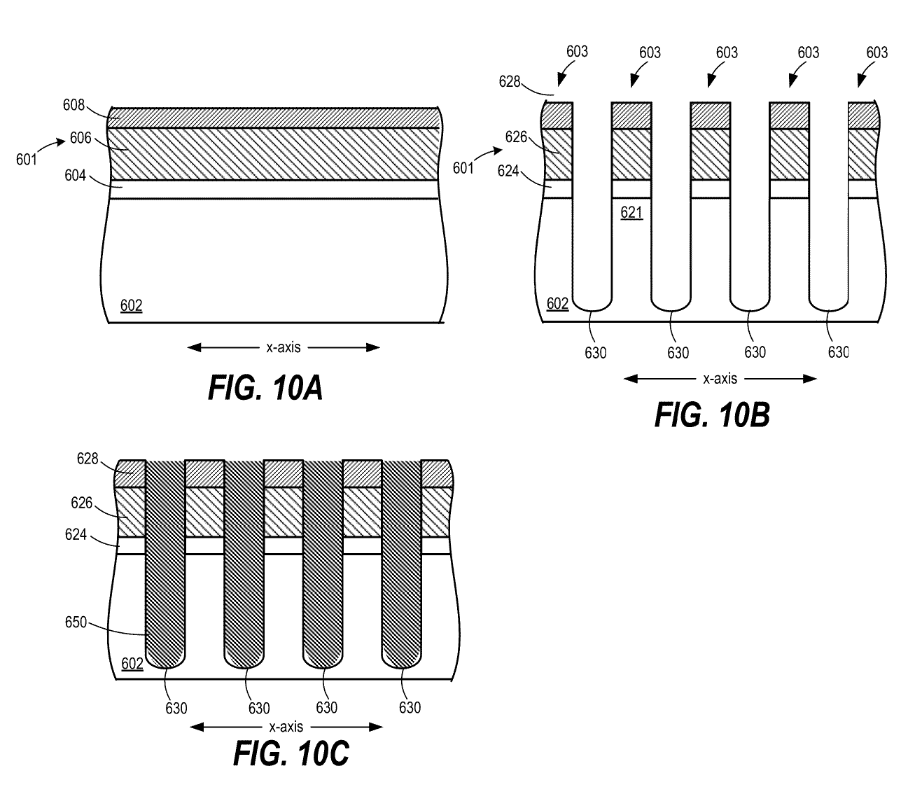

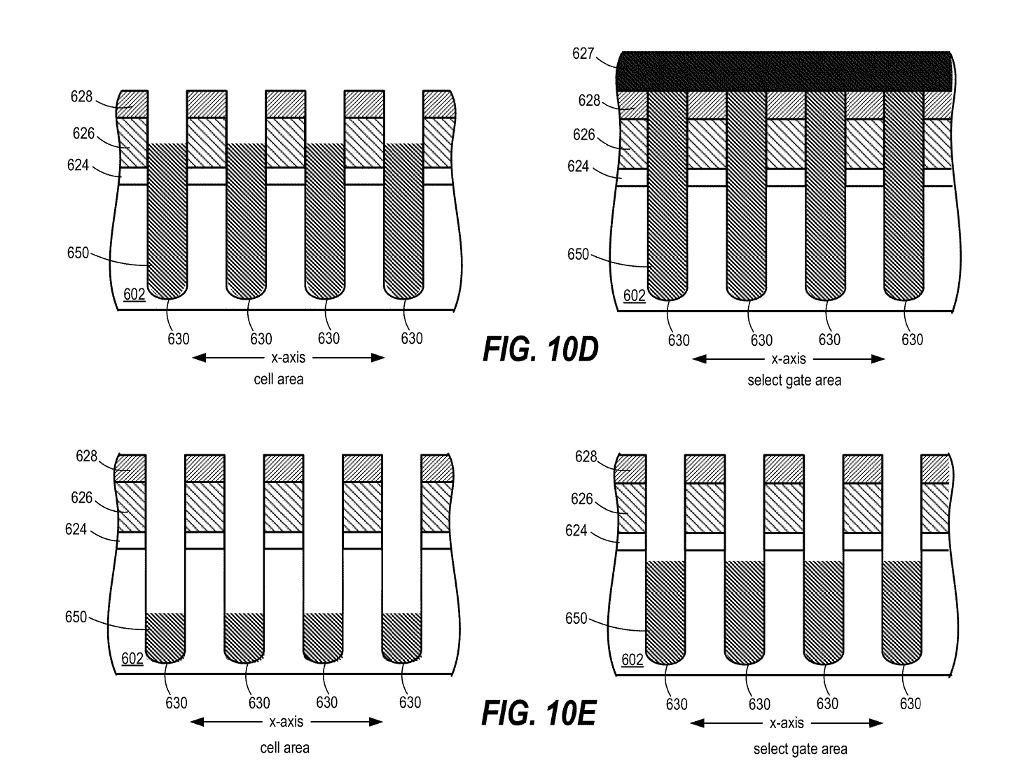

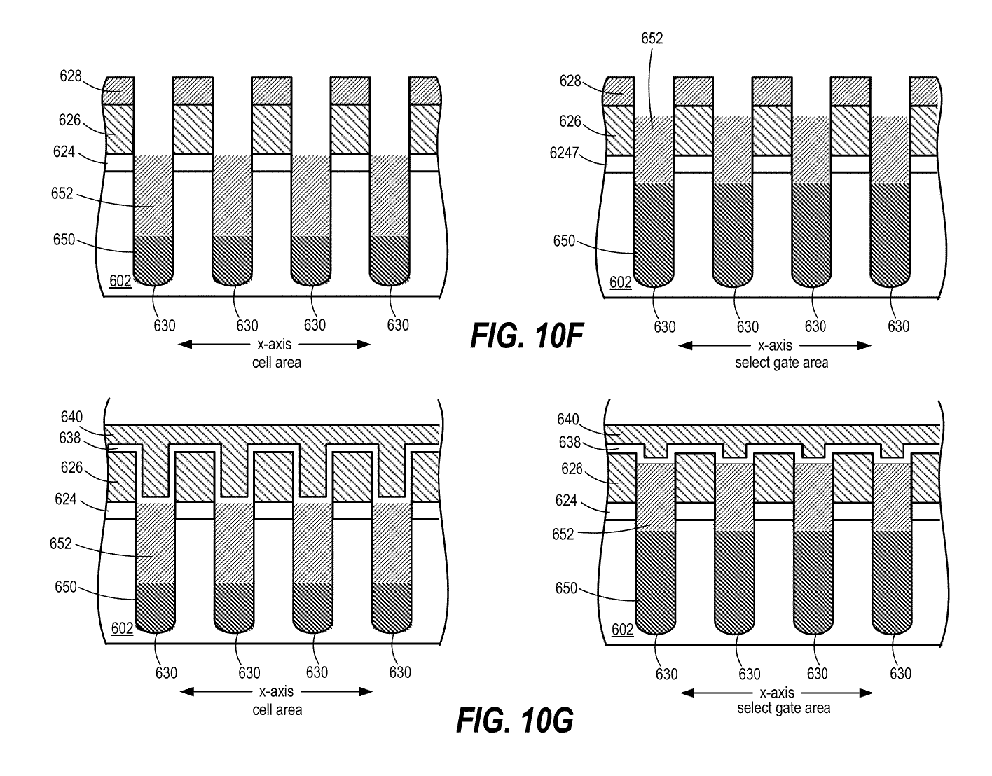

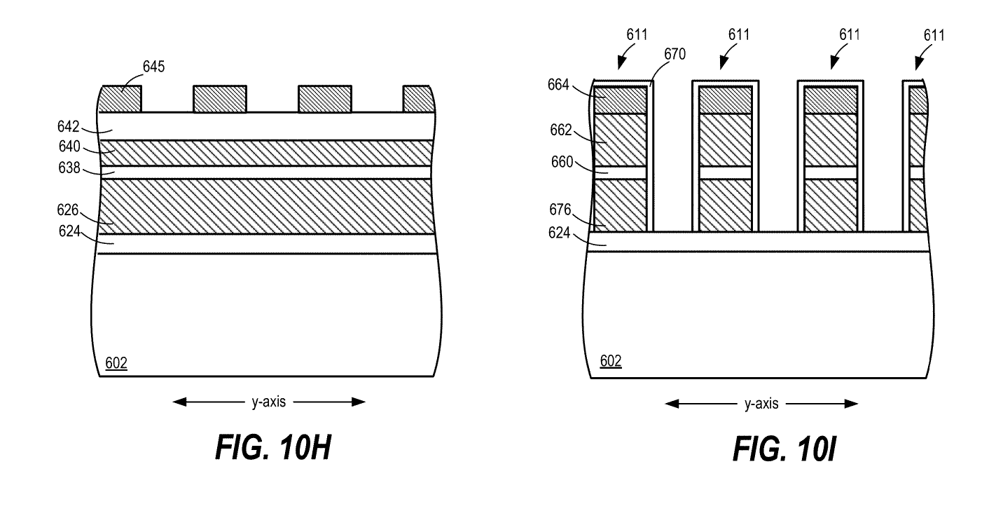

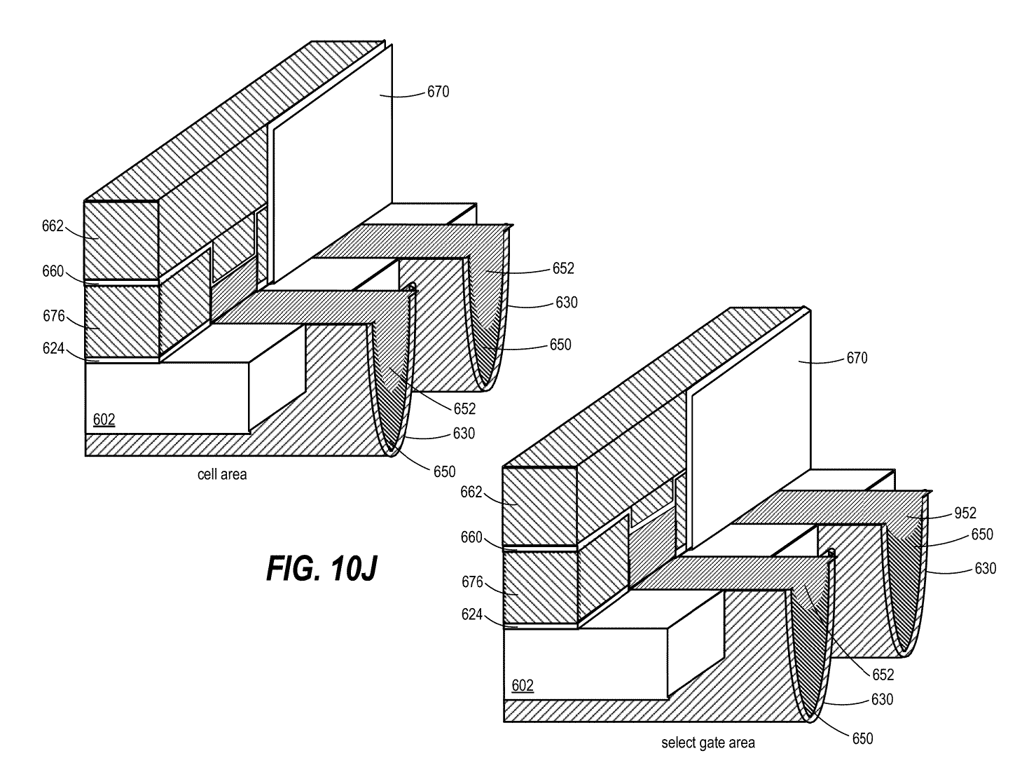

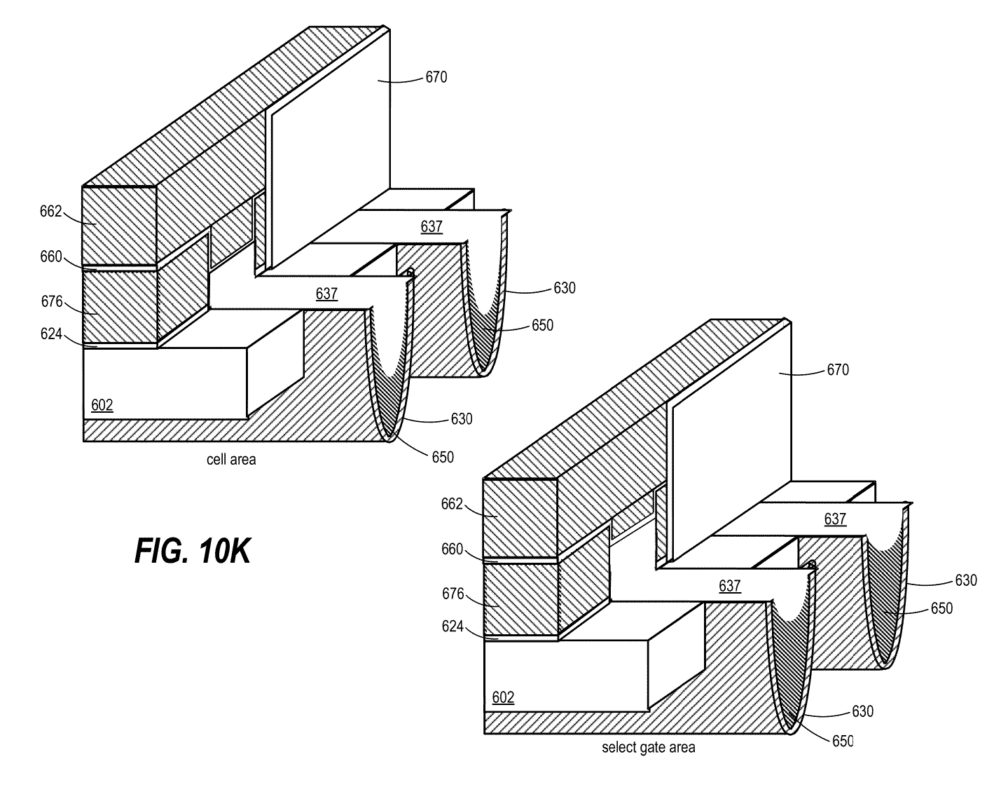

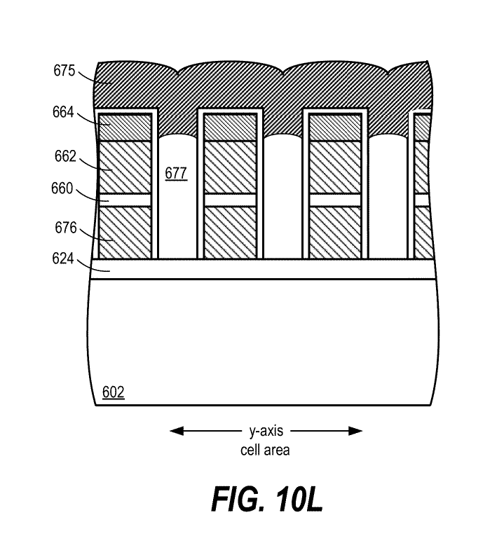

FIG. 9 is a flowchart describing a method of fabricating non-volatile storage with air gap isolation in accordance with one embodiment. FIGS. 10A-10L are orthogonal cross-sectional views of one example of a non-volatile memory array that can be fabricated according to the method in FIG. 9. Processing in the row or word line direction is first depicted, including the formation of active areas in the substrate, separated by isolation regions. Air gaps are formed in the bit line or column direction as part of the isolation regions. The described embodiment is exemplary only and its precise form should not be taken as limiting the disclosure. The exact materials, dimensions and order of processing may vary according to the requirements of a given implementation. It is noted that the dimensions of the various features are not necessarily drawn to scale.

At step 502, initial processing is performed to prepare a substrate for memory fabrication. One or more wells (e.g., a triple well) are typically formed in the substrate prior to forming a layer stack over the substrate surface. For example, a p-type substrate may be used. Within the p-type substrate, an n-type well may be created and within the n-type well a p-type well may be created. Various units of a memory array may be formed within individual p-type wells. The well(s) can be implanted and annealed to dope the substrate. A zero layer formation step may also precede well formation.

At step 504, an initial layer stack is formed over the substrate surface. FIG. 10A is a cross-sectional view along the x-axis in the row or word line direction of a memory array 600 showing a layer stack 601 formed over the surface of a substrate 602. In this example, layer stack 601 includes a tunnel dielectric layer (TDL) 604, a charge storage layer (CSL) 606, and a sacrificial layer (SL) 608. One or more hard masking layer(s) (HML), not shown, may also be formed. It is noted that a layer may be said to be over another layer when one or more layers are between the two layers as well as when the two layers are in direct contact.

The tunnel dielectric layer 604 is a thin layer of oxide (e.g., SiO₂) grown by thermal oxidation in one embodiment, although different materials and processes can be used. Chemical vapor deposition (CVD) processes, metal organic CVD processes, physical vapor deposition (PVD) processes, atomic layer deposition (ALD) processes, or other suitable techniques can be used to form the various layers described herein except where otherwise noted. In one example, the tunnel oxide layer is formed to a thickness of about 8 nanometers (nm). Although not shown, one or more high voltage gate dielectric regions may be formed at a peripheral circuitry region before or after forming the tunnel dielectric layer. The high voltage gate dielectric regions may be formed with a larger thickness (e.g., 30-40 nm) than the tunnel dielectric layer.

The charge storage layer is a polysilicon floating gate layer in one embodiment. The vertical dimension (with respect to the substrate surface) or thickness of the charge storage layer can vary by embodiment. In one example, the charge storage layer has a vertical dimension of 30 nm. In another example, the charge storage layer has a vertical dimension of 50-80 nm.

Dielectric charge storage materials, metal and non-metal nanostructures (e.g., carbon) can also be used for the layer of charge storage material. In one embodiment, the charge storage layer is a metal layer forming a charge-trap type floating gate layer. A thin metal charge-trap type floating gate can reduce concerns with ballistic charge programming issues that may arise with conventional polysilicon floating gates. In one embodiment, a metal floating gate layer is formed to a thickness of between 10 nm and 20 nm. In another embodiment, metal thicknesses greater than 20 nm or less than 10 nm are used. In one embodiment, the metal floating gate layer is a high work function metal. In one example, the metal is ruthenium. Other metals such as titanium, tungsten, tantalum, nickel, cobalt, etc., and their alloys (e.g., TiN, WN, TaN, NiSi, CoSi, WSix) can be used.

The sacrificial layer 608 is a layer of silicon nitride (SiN) in one embodiment although other materials can be used. Hard masking layer(s) such as oxides or combinations of oxides and nitrides can be used in addition to other materials.

The layer stack is patterned at step 506. The first pattern applied at step 506 corresponds to intended columns of the memory array and may be repetitive in the row or direction of the x-axis. The pattern also corresponds to intended active areas of the substrate which will be separated by isolation regions. In one embodiment, conventional photolithography using photoresist is used to pattern the hard mask layer(s) into strips elongated in the direction of the y-axis with spaces between strips adjacent in the direction of the x-axis. The hard mask layer may be patterned into a first sub-pattern at the memory array area and one or more different sub-patterns at the peripheral circuitry areas to define active areas in the substrate with different dimensions in the direction of the x-axis. Spacer-assisted patterning, nano-imprint patterning, and other patterning techniques can also be used to form strips of the hard mask layer at reduced features sizes. The pattern, repetitive in the second or row direction, may define a first direction of etching to form columns of the targeted memory array.

After forming the pattern, the layer stack is etched at step 508 and the substrate is etched at step 510. The layer stack and substrate are both etched using the first pattern formed in step 506. The layer stack is etched into layer stack columns. The substrate is etched into active areas which underlie the columns and isolation regions which separate the active areas. The term layer stack is used to refer to the layers formed over the substrate throughout processing. Thus, layer stack 601 may refer to the collection of layer stack columns that result from etching the initial layer stack. In one embodiment, reactive ion etching is used with various combinational etch chemistries to etch the different layers, however, any suitable etch process(es) can be used.

FIG. 10B depicts the memory array after etching in one example. Etching forms layer stack columns 603 that are elongated in the direction of the y-axis with spaces therebetween in the direction of the x-axis. Each layer stack column 603 includes a tunnel dielectric strip (TDS) 624, a charge storage strip (CSS) 626, and a sacrificial strip (SS) 628. The substrate is etched to form isolation regions and active areas that underlie the layer stack columns. In FIG. 10B, isolation regions 630 are separated by active areas 621 under each layer stack column 603. In one example, the depth of the isolation regions in the substrate is 200 nm. Various depth can be used, for example, ranging from 150-220 nm in one embodiment.

At step 512, the isolation regions are filled with a dielectric fill material. The fill material is formed in the isolation regions as well as the spaces between adjacent layer stack columns. The fill material can be planarized, such as by chemical mechanical polishing (CMP), resulting in the structure shown in FIG. 10C including fill material 650. A dielectric liner may be formed before the fill material in other embodiments. For example, a thermally grown oxide such as can be formed using direct partial oxidation or a high temperature oxide (HTO) may be used. In one embodiment, the fill material 650 is a spin on dielectric (SOD) having a high etch selectivity with respect to a liner. Oxides or other fill materials may be used.

At step 514, the select gate areas are covered with a mask and at step 516, an etchback process is performed to recess the dielectric fill material at the cell area, while protecting the select gate area from etching. Standard photolithography using photoresist or other processes may be used to form the mask, including one or more strips elongated in the intended row direction of the select gate areas, extending in the column direction over multiple intended rows of select gates. FIG. 10D depicts the results of steps 514 and 516 in one example. FIG. 10D depicts a cross-sectional view at part of an intended cell area and select gate area to show the different processing at each region. A pattern or mask 627 extends over the intended select gate area, while leaving the intended cell area exposed.

The dielectric material may be etched back to various depths. Wet etching or dry reactive ion etching may be used. FIG. 10D depicts the fill material with an upper surface between the level of the upper surface of the tunnel dielectric strips and charge storage strips but less or more etching may be used.

At step 518, the mask is removed and at step 520, additional etching may be performed to further recess the fill material at both the cell and select gate areas. Additional etching may be used to tailor the target endpoint for the air gaps at both the select gate area and cell area. The upper surface of the fill material will define the lower endpoint of the subsequently formed air gaps. FIG. 10E depicts the result of steps 518 and 520 in one example. The upper surface of the fill material 650 is recessed to a depth below the surface of substrate 602 at the cell area. In one embodiment, the distance between the upper surface of the fill material 652 and the substrate surface is 100 nm. Various distances may be used, however. For example, a range of 50-150 nm can be used in one embodiment. At the select gate area, the fill material is recessed to a level below the substrate surface but much less than at the cell area. For example, it may be 10-50 nm below the surface, or may even extend above the substrate surface. If a liner is used, material 650 may be subjected to less annealing to achieve a suitable etch selectivity so that the fill material is recessed, while leaving the liner along the vertical sidewalls of the layer stack columns and isolation regions.

At step 522, an optional sacrificial film may be formed in the remaining portions of the isolation regions and also the spaces between layer stack columns. In one embodiment, the sacrificial film is a spin-on dielectric (SOD). In one example, the sacrificial film is a borosilicate glass (BSG) or other type of oxide. In another example, a spin-on-carbon can be used. Other materials can also be used such as polysilicon, silicon nitride (SiN) or an undensified polysilazane (PSZ) such as a PSZ-based inorganic spin-on-glass (SOG) material. The sacrificial film can be chosen for a high etch selectivity with respect to the dielectric fill material and any liner that is used so that it etches at a faster rate. In one example, the etch selectivity of the sacrificial film is achieved by skipping anneals. In another example, the fill material 650 itself can be undensified PSZ.

At step 524, the sacrificial film is recessed at the cell and select gate areas. FIG. 10F depicts the results of steps 522 and 524 in one example. The sacrificial film has an upper surface near the level of the upper surface of the tunnel dielectric layer at the cell area and between the lower and upper surfaces of the charge storage layer at the select gate area. Various depths of recess may be used. The upper surface of the sacrificial material will define the upper endpoint region of the subsequently formed air gaps. As is illustrated, the sacrificial material only extends a small distance below the substrate surface at the select gate area, when compared with its extension at the select gate area. Accordingly, the dielectric fill material will extend further toward and even to or above the substrate surface to from the blocking layer to prevent subsequent processing from forming materials in the intended air gaps at the cell areas.

At step 526, an intermediate dielectric layer and control gate layer are formed. The intermediate dielectric layer is a triple layer of oxide, nitride and oxide (ONO) in one embodiment having a thickness of about 9-12 nm, although various materials and thicknesses may be used. In one embodiment, a high-K (dielectric constant) material is used for the intermediate dielectric to reduce or eliminate charge transfer through the intermediate layer while providing enhanced control gate to floating gate coupling. The control gate layer is polysilicon in one embodiment. The polysilicon can be doped in-situ or after formation. In another embodiment, the control gate layer is formed at least partially of a metal. In one example, the control gate layer has a lower portion that is formed from polysilicon and an upper portion that is formed from metal. A barrier layer may be formed between the polysilicon and the metal, to prevent silicidation. The control gate layer can include, by way of example (from layers to upper layers as move away from substrate surface): a barrier metal and metal; a barrier metal, polysilicon and silicide; a barrier metal and silicide (e.g., FUSI); polysilicon, a barrier metal and metal. Barrier metals may include, but are not limited to, Ti, TiN, WN and TaN or a combination with related alloys that have a suitable electron work function. Metals may include, but are not limited to, W, WSix or other similar low resistivity metals. Silicides may include, but are not limited to, NiSi, CoSi. In one example, the control gate layer is polysilicon that is subjected to silicidation after being etched into control gates so as to form a partially or fully-silicided control gate structures. The control gate layer may be formed by chemical vapor deposition (CVD), atomic layer deposition (ALD), plating, or another technique.

FIG. 10G depicts the results of 526 in one embodiment. Intermediate dielectric layer 640 is formed over the substrate. A conformal deposition process is used in this example so that the intermediate dielectric layer is formed to a substantially even thickness along the sidewalls and upper surface of each charge storage strip 626. Control gate layer 640 is formed over the intermediate dielectric layer 638. The control gate layer is a layer of polysilicon in one example, formed to a depth of about 100 nm, although various materials (e.g., metal) can be used and formed to different thicknesses.

At step 528, a second pattern is formed over the layer stack. The second pattern is formed for etching orthogonal to the direction of etching using the first pattern. The second pattern may include strips of hard masking material and/or photoresist, or other suitable mask, that are elongated in the row direction along the x-axis with a spacing between strips in the column direction along the y-axis. The pattern can be used to define the gate length for the charge storage region of each memory cell.

FIG. 10H is a cross-sectional view taken along line B-B of FIG. 10G, depicting the device in cross-section in the direction of the y-axis or bit line direction. FIG. 10H depicts the results of step 528 after forming the second pattern. Over the control gate layer 640 is formed one or more hard masking layers 642. Strips 645 of photoresist or another patterning agent are applied. In one embodiment, the strips correspond to intended column dimensions for the control gates and charge storage regions. In another example, the strips may be used to form spacers for double patterning process. Etching according to the second pattern will be used to define the gate length of the charge storage regions and select gate regions extending in the column or bit line direction. Although a pattern is only shown for the cell area, the pattern will be formed at the select gate area as well to etch the select gate regions. The pattern may include wider (larger dimension in the column direction) strips at the select gate area to form larger gate lengths as shown in FIG. 8.

At step 530, the layer stack is etched into layer stack rows. In one embodiment, etching the layer stack includes etching strips of the tunnel dielectric material. In another embodiment, the tunnel dielectric is not etched. Reactive ion or another suitable etch process may be used. One or more etch chemistries may be applied to etch through the various layers of the stack.

FIG. 10I depicts the results of step 530. Etching continues until reaching the tunnel dielectric layer in this example. In other examples, etching may continue until reaching the substrate surface. In another example, some portion of the tunnel dielectric layer is etched without completely etching through the layer. Etching forms layer stack rows 611. The hard masking material is etched into hard mask strips (HMS) 664 and the control gate layer is etched into control gates (CG) 662. In one embodiment, the control gates 662 form word lines. The intermediate dielectric layer 638 is etched into intermediate dielectric strips 660. The charge storage strips 636 are etched into individual charge storage regions (CSR) or floating gates 676.

At step 532, a protective sidewall film is formed along the vertical sidewalls of the layer stack rows. Different films may be used in different implementations. In one example, an oxide can be deposited and etched back to form sidewall films along the sidewalls of the individual layer stack rows. Traditional spacer formation processes may be used. FIG. 10I depicts a protective sidewall spacer 670 that is formed along the sidewall (extending in the word line direction) of one of the layer stack rows. The sidewall spacer is depicted as only partially extending along the sidewall in the x-axis direction for clarity. The spacer will actually extend fully along the length of each layer stack row. Each layer stack row will include two sidewall spacers, with one on each vertical sidewall. After protective sidewall film deposition, an implant process can be performed to create n+ source/drain regions. In one embodiment, the n+ source/drain regions are created by implanting n-type dopants such as arsenic or phosphorus into the p-well.

The sidewall spacers will protect each layer stack row during subsequent processing steps. In one embodiment, the spacer material is chosen for its etch selectivity with respect to the sacrificial film 652. In this manner, the sacrificial film can later be removed in processes where the layer stack sidewalls are not exposed to the various etch chemistries. This will protect the sidewalls of the control gate layer and charge storage layer as well at the various dielectric layers.

FIG. 10J is a perspective view of the memory array depicting the point in processing shown in the cross-sectional views of FIG. 10I. Protective dielectric liner 670 is formed along the sidewall of one of the layer stack rows 611. The liner 670 is depicted as only partially extending along the sidewall in the x-axis direction for clarity. The spacer will actually extend fully along the length of each layer stack row. Each layer stack row will include liners 670 on each vertical sidewall.

The liner will protect each layer stack row during subsequent processing steps. In one embodiment, the liner material is chosen for its etch selectivity with respect to the sacrificial film 652. In this manner, the sacrificial film can later be removed in processes where the layer stack sidewalls are not exposed to the various etch chemistries. This will protect the sidewalls of the control gate layer and charge storage layer as well as the various dielectric layers.

FIG. 10J illustrates that etching back the liner material exposes the sacrificial material 652 in trenches 630. A portion of an upper surface of the sacrificial material corresponding to the spaces between adjacent layer stack rows is exposed. This allows subsequent processing to remove the sacrificial material in order to form an air gap in the bit line direction.

At step 534, the sacrificial material is removed to form the bit line air gaps. A wet etch chemistry is used in one embodiment, although other suitable reactive ion etch (RIE) processes (e.g., dry) can be used. As earlier described, the etch process is selective for the sacrificial film so that it can be removed without removing the liner in the isolation regions and the sidewalls spacers on the layer stack rows.

FIG. 10K depict the results of step 534 in one embodiment. Sacrificial material 652 has been removed from isolation regions 630 and the areas between layer stack columns. Etching removes the film from the isolation regions, beginning with the material exposed by etching back liner 670. A wet etch process is used in one embodiment, although other suitable etch processes (e.g., dry) can be used. As earlier described, the etch process is selective for the sacrificial film so that it can be removed without removing the liner in the isolation regions and the sidewalls spacers on the layer stack rows. Etching will also remove the sacrificial material in the isolation regions that underlies the layer stack rows. Etching will begin attacking the sacrificial material from the side under the rows after etching proceeds vertically down into the isolation regions. Etching will further continue behind the liner to remove portions of the sacrificial material that extend above the isolation regions and substrate surface. Etching removes the material between charge storage regions and intermediate dielectric that are adjacent in the word line or row direction. Some of the sacrificial material may not be removed. Thus, removing the sacrificial material does not necessarily have to include removing all of the material.

Removing the sacrificial material forms air gaps 637. The air gaps are elongated in the column direction in the isolation regions 630. The air gaps extend from below the surface of the substrate to the level of the upper surface of the intermediate dielectric regions. As earlier described, the air gaps may have different vertical dimensions in different embodiments. The air gaps may not extend as deep within isolation regions and may not extend as far above the substrate surface. Further, the air gaps may be formed exclusively within the isolation regions or exclusively between adjacent layer stack columns in other examples.

At step 536, air gaps are formed at least partially in the spaces between the layer stack rows. The air gaps are elongated in the x-direction. They extend in the x-direction to provide electrical isolation or shielding between elements of adjacent layer stack rows. The vertical dimension and column dimension (along y-axis) of the air gaps can vary to meet the particular requirements of a given implementation.

FIG. 10L depicts the results of step 526 in an example where a capping layer 475 is formed over the layer stack rows using a non-conformal deposition process. A dielectric liner (e.g., oxide) is formed along the sidewalls and over the layer stack rows. Capping layer 675 accumulates by using a non-conformal deposition process and meets at a location over the spaces between rows to form air gaps 677 that are elongated in the x-direction. Material 675 extends vertically toward the substrate surface along the liner on a portion of the vertical sidewalls of the layer stack rows. The amount of this vertical dimension will define an upper endpoint of the air gaps at a lower surface of material 675. In this example, it is seen that the air gap extends vertically beyond the level of the upper surface of control gate strips 662. Although not shown, some portion of dielectric 675 may enter the spaces between rows. This portion of the dielectric may raise the lower endpoint of the air gap. Any accumulation will be minor and only decrease the size of the air gap minimally. Although not shown, a polishing step can be applied to form individual caps from layer 675. The capping layer can be polished to form plugs sealing the word line air gaps. A planar surface can be created for further processing steps. The vertical dimension (with respect to substrate surface) and row dimension (along x-axis) of the air gaps can vary to meet the particular requirements (e.g., suitable isolation parameters) of a given implementation.

At step 546, front end processing is completed. In one example, step 546 may include interconnecting the floating gate and control gate regions of select and peripheral circuitry transistors. Peripheral gate connections can be formed using vias or contact holes, etc. to form contacts to individual gate regions or to connect multiple transistors to a common control line. The select gate transistors can have their floating gate regions shorted to the control gate regions to form a single gate structure. Array connections can also be patterned and formed. After forming contacts, etc., further backend processing to form metal layers, etc. to complete the device according to known techniques can be performed. Various backend processes can be performed to finalize fabrication of the array. For example, a passivation dielectric layer can be deposited, followed by forming metal conductive lines and vias to connect the lines with source and drain regions at the end of the memory cell strings, etc.

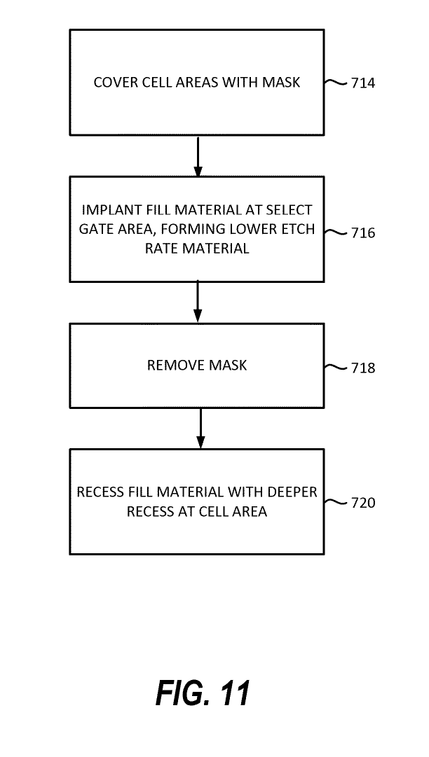

FIG. 11 is a flowchart describing another embodiment using a select implant to inhibit or reduce the etch rate of a dielectric fill material in the select gate areas. Processing can proceed as described in FIG. 9. After step 512, however, the cell area(s) can be covered with a mask at a step 714 rather than covering the select gate areas as in step 514 of FIG. 9.

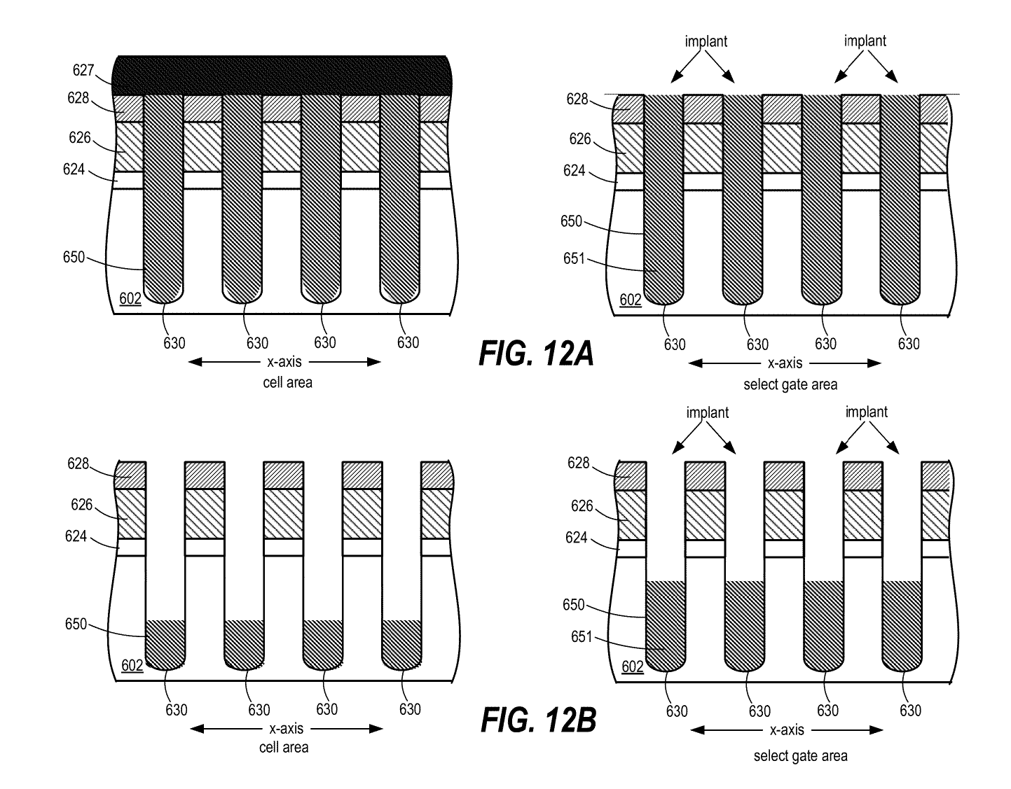

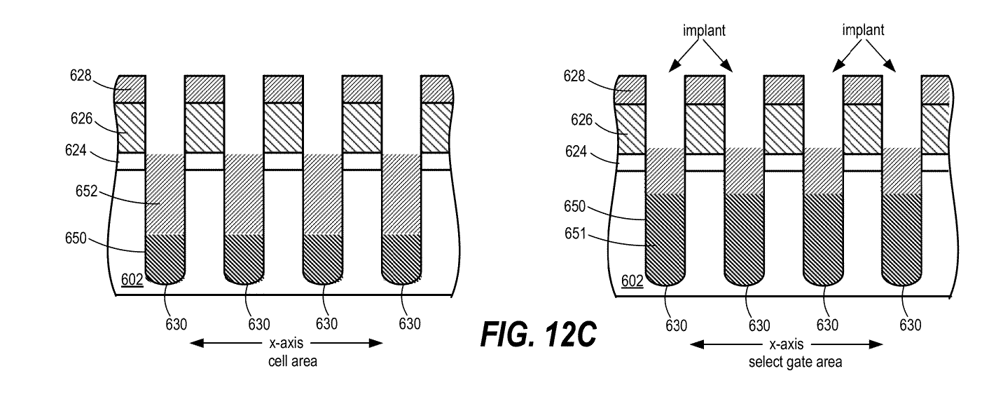

At step 716, in one embodiment the fill material at the select gate areas is selectively implanted or doped while inhibiting implanting at the cell area by the mask. The selectively doped material at the select gate areas will etch slower than the undoped material at the cell areas. In another example, the fill material at the cell areas is selectively implanted or doped while inhibiting implanting at the select gate area by the mask. The selectively doped material at the cell areas will etch faster than the undoped material at the select gate areas. FIG. 12A depicts the results of steps 714 and 716 in one embodiment.

At step 718, the mask is removed from the cell area and the fill material is recessed at step 720. Wet or dry reactive ion etching may be used. FIG. 12B depicts the results of step 718 in one example. The etch will be deeper or faster at the cell area forming a deeper recess in the isolation regions at the cell areas. The sacrificial material 652 can then be formed and recessed as shown in FIG. 12C. The additional dielectric fill material at the select gate areas forms a blocking layer from the additional fill material at these areas. After step 720, processing can proceed as described in FIG. 9.

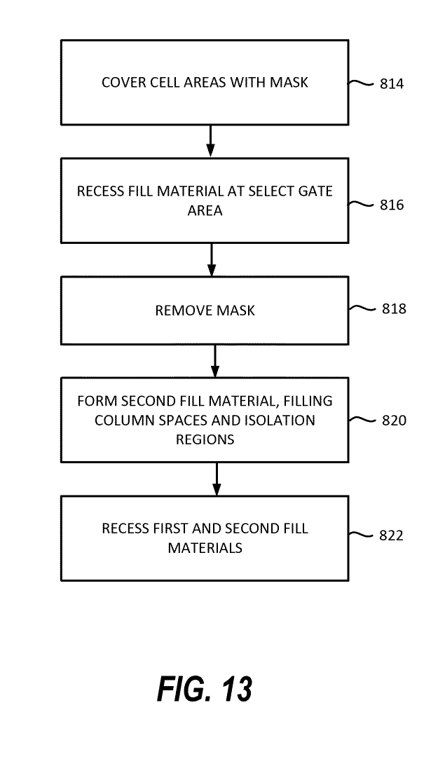

FIG. 13 is a flowchart describing another embodiment where a different fill material is introduced selectively at the select gate areas to form a blocking layer and aid air gap formation at the cell areas. Processing can proceed as described in FIG. 9. After step 512, however, the cell area(s) can be covered with a mask at a step 814 rather than covering the select gate areas as in step 514 of FIG. 9.

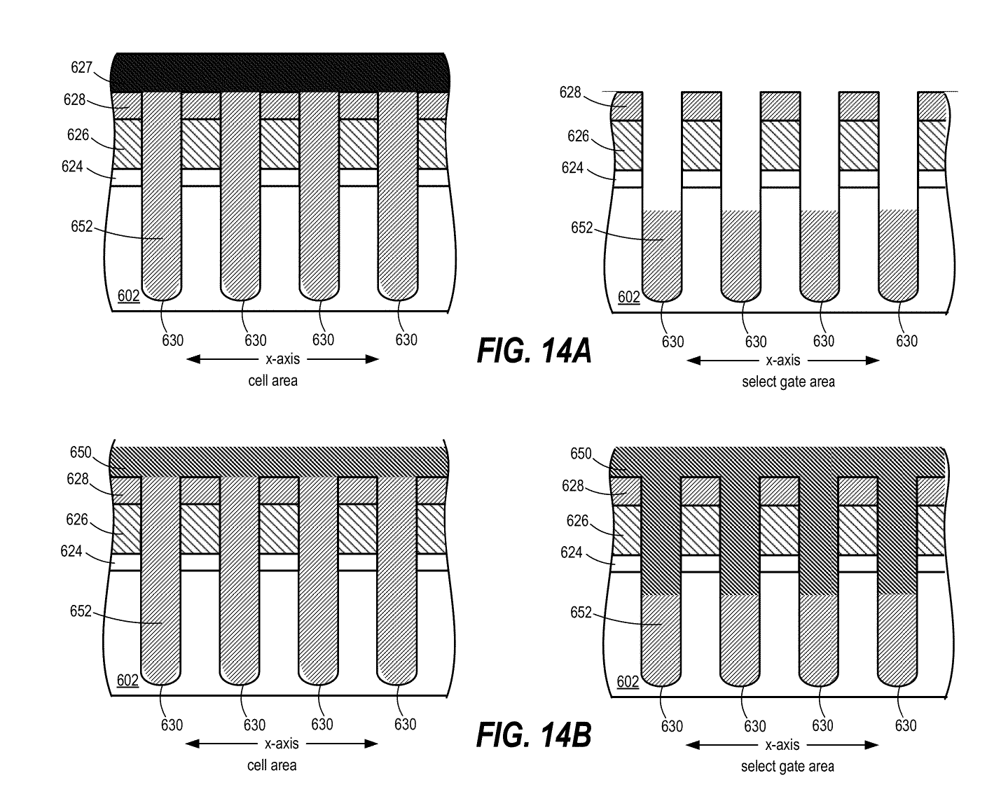

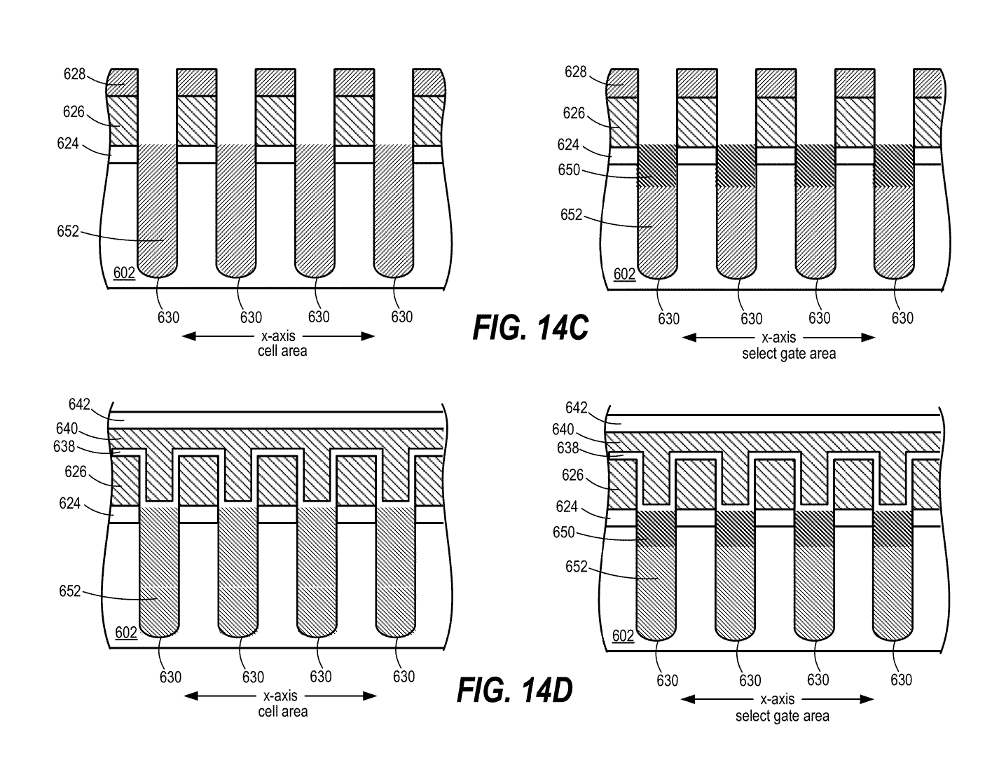

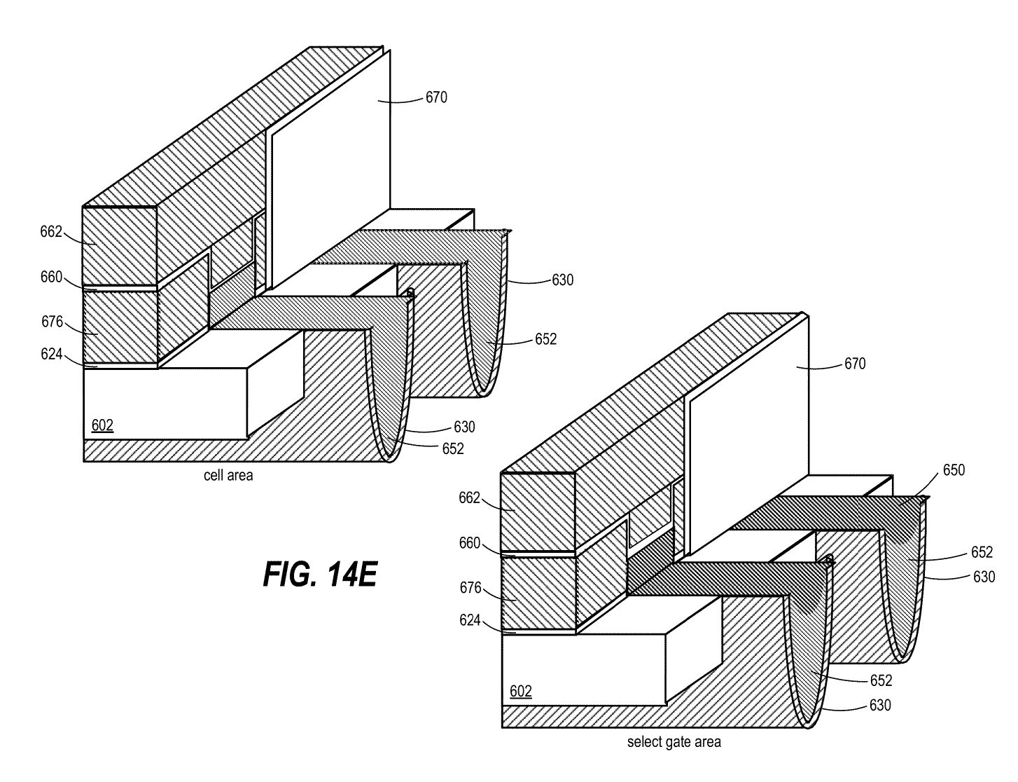

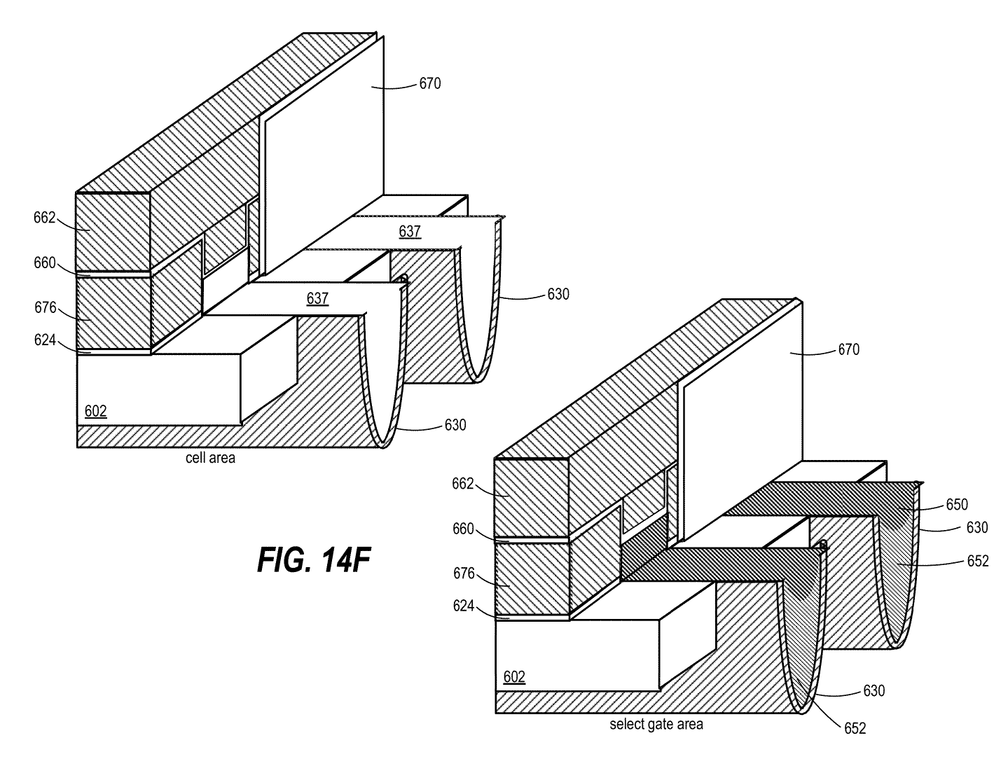

At step 816, the fill material at the exposed select gate areas can be recessed using the mask to inhibit or block etching at the cell areas. FIG. 14A depicts the results of steps 714 and 716 in one embodiment.

At step 818, the mask is removed from the cell area and at step 820 a second fill material is formed, filling the spaces between columns and the isolation regions. FIG. 14B depicts the results of step 816 and 818 in one embodiment. The second fill material 650 is a lower etch rate material than the first fill material. In one embodiment, the second fill material is a high-density plasma oxide or other type of oxide. Undoped oxides may be used to form lower etch rate materials.

After filling with the second lower etch rate material, the first and second fill materials are recessed at step 822. Wet reactive ion or dry etching may be used. FIG. 14C depicts the results of step 822 in one embodiment. The etch will be deeper or faster at the cell area because of the higher etch rate material 652 there. Material 650 etches slower at the select gate area. In this embodiment, the resulting surfaces of the first and second fill materials are at equal or near equal levels vertically relative to the substrate surface. In other embodiment, a deeper recess may be formed in the isolation regions at the cell areas but this is not required. Processing then proceeds as described in FIG. 9. FIG. 14D depicts the formation of intermediate dielectric layer 638, control gate layer 640, and a masking layer 642. FIG. 14E is a perspective view after etching in the row direction and forming protective liner 670. The higher etch rate material 652 in the isolation regions at the cell area is shown, completely occupying these regions. At the select gate area, the higher etch rate material 652 is partially formed in the isolation regions but is overlayed by the lower etch rate material 650. Layer 650 forms a blocking layer to inhibit etching. FIG. 14F depicts the results of additional processing to remove the higher etch material as described above. Etching forms bit line or STI air gaps 637 which may extend the full height of the STI or the air gap may be partially formed within the STI. The air gaps are only formed at the cell areas in this example. In another embodiment, air gaps may be partially formed at the select gate areas. However, material 650 will block or at least slow down etching at these areas as shown in FIG. 14F. This forms a blocking material to result in air gap formation at the cell areas only.

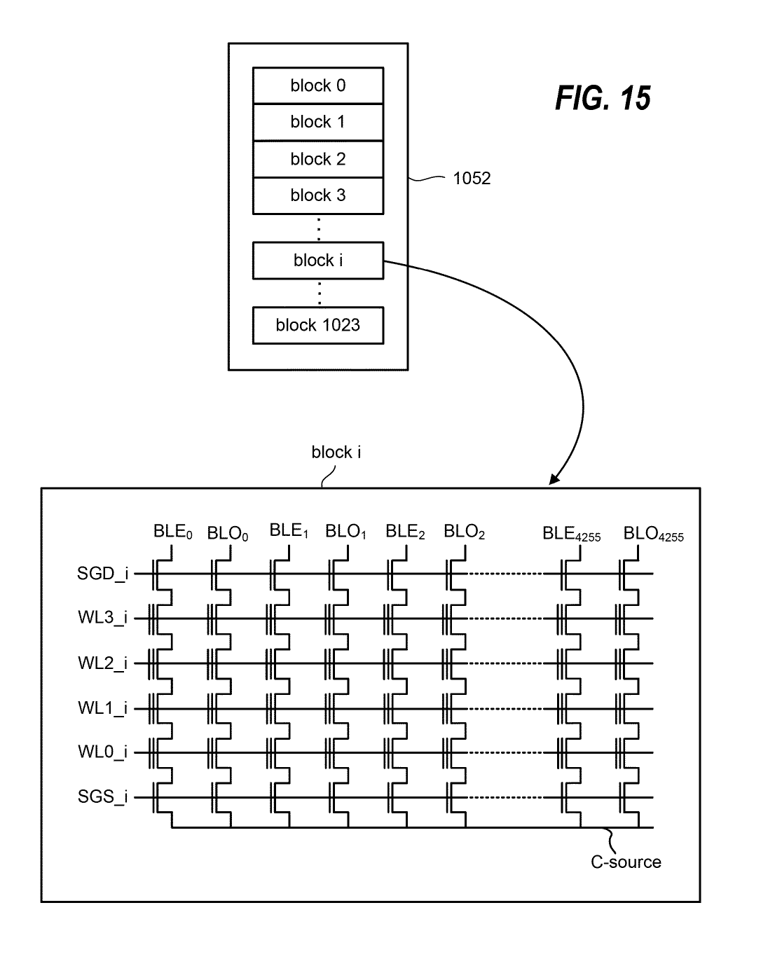

FIG. 15 depicts an exemplary structure of a memory cell array 1052 that can be fabricated using one or more embodiments of the disclosed technology. As one example, a NAND flash EEPROM is described that is partitioned into 1,024 blocks. The data stored in each block can be simultaneously erased. In one embodiment, the block is the minimum unit of cells that are simultaneously erased. In each block, in this example, there are 8,512 columns that are divided into even columns and odd columns. The bit lines are also divided into even bit lines (BLE) and odd bit lines (BLO). FIG. 15 shows four memory cells connected in series to form a NAND string. Although four cells are shown to be included in each NAND string, more or less than four can be used (e.g., 16, 32, or another number). One terminal of the NAND string is connected to a corresponding bit line via a first select transistor (also referred to as a select gate) SGD, and another terminal is connected to c-source via a second select transistor SGS.

During read and programming operations for memory cells of one embodiment, 4,256 memory cells are simultaneously selected. The memory cells selected have the same word line (e.g. WL2-i), and the same kind of bit line (e.g. even bit lines). Therefore, 532 bytes of data can be read or programmed simultaneously. These 532 bytes of data that are simultaneously read or programmed form a logical page. Therefore, in this example, one block can store at least eight pages. When each memory cell stores two bits of data (e.g. a multi-level cell), one block stores 16 pages. In another embodiment, a memory array is formed that utilizes an all bit-line architecture such that each bit line within a block is simultaneously selected, including those adjacent in the x-direction.

In other embodiments, the bit lines are not divided into odd and even bit lines. Such architectures are commonly referred to as all bit line architectures. In an all bit line architecture, all the bit lines of a block are simultaneously selected during read and program operations. Memory cells along a common word line and connected to any bit line are programmed at the same time. In other embodiments, the bit lines or block can be broken up into other groupings (e.g., left and right, more than two groupings, etc.).

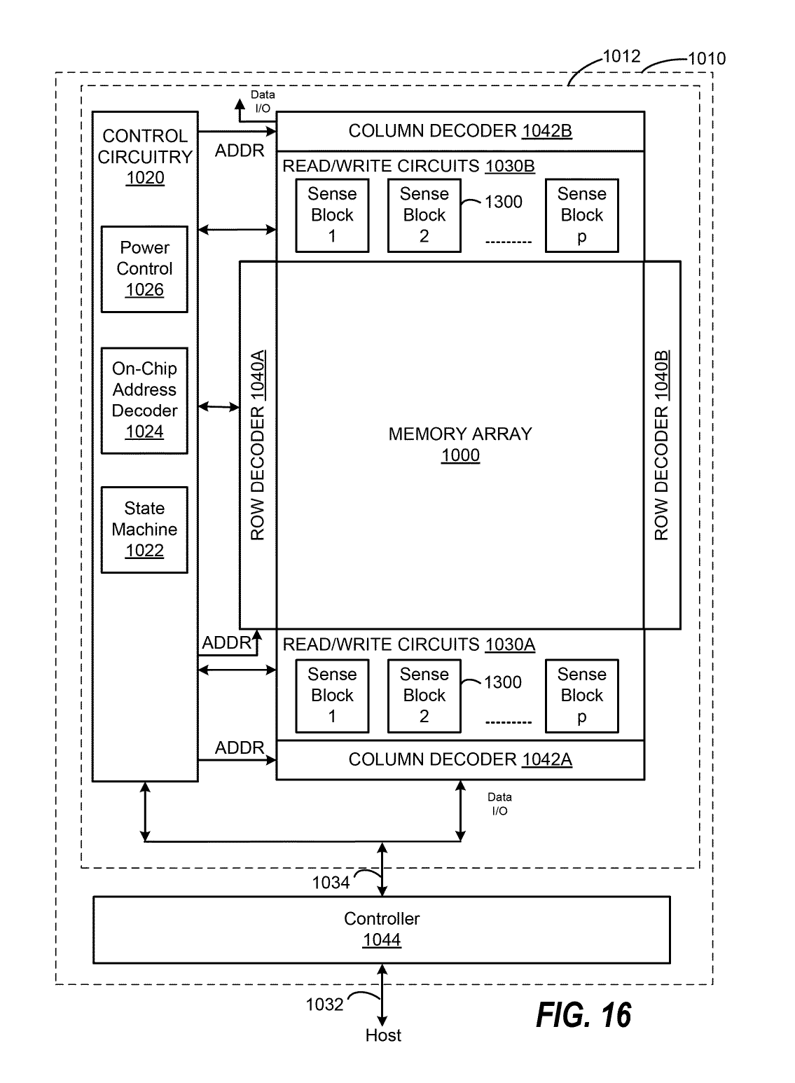

FIG. 16 illustrates a non-volatile storage device 1010 that may include one or more memory die or chips 1012. Memory die 1012 includes an array (two-dimensional or three dimensional) of memory cells 1000, control circuitry 1020, and read/write circuits 1030A and 1030B. In one embodiment, access to the memory array 1000 by the various peripheral circuits is implemented in a symmetric fashion, on opposite sides of the array, so that the densities of access lines and circuitry on each side are reduced by half. The read/write circuits 1030A and 1030B include multiple sense blocks 1300 which allow a page of memory cells to be read or programmed in parallel. The memory array 1000 is addressable by word lines via row decoders 1040A and 1040B and by bit lines via column decoders 1042A and 1042B. In a typical embodiment, a controller 1044 is included in the same memory device 1010 (e.g., a removable storage card or package) as the one or more memory die 1012. Commands and data are transferred between the host and controller 1044 via lines 1032 and between the controller and the one or more memory die 1012 via lines 1034. One implementation can include multiple chips 1012.

Control circuitry 1020 cooperates with the read/write circuits 1030A and 1030B to perform memory operations on the memory array 1000. The control circuitry 1020 includes a state machine 1022, an on-chip address decoder 1024 and a power control module 1026. The state machine 1022 provides chip-level control of memory operations. The on-chip address decoder 1024 provides an address interface to convert between the address that is used by the host or a memory controller to the hardware address used by the decoders 1040A, 1040B, 1042A, and 1042B. The power control module 1026 controls the power and voltages supplied to the word lines and bit lines during memory operations. In one embodiment, power control module 1026 includes one or more charge pumps that can create voltages larger than the supply voltage.

In one embodiment, one or any combination of control circuitry 1020, power control circuit 1026, decoder circuit 1024, state machine circuit 1022, decoder circuit 1042A, decoder circuit 1042B, decoder circuit 1040A, decoder circuit 1040B, read/write circuits 1030A, read/write circuits 1030B, and/or controller 1044 can be referred to as one or more managing circuits.

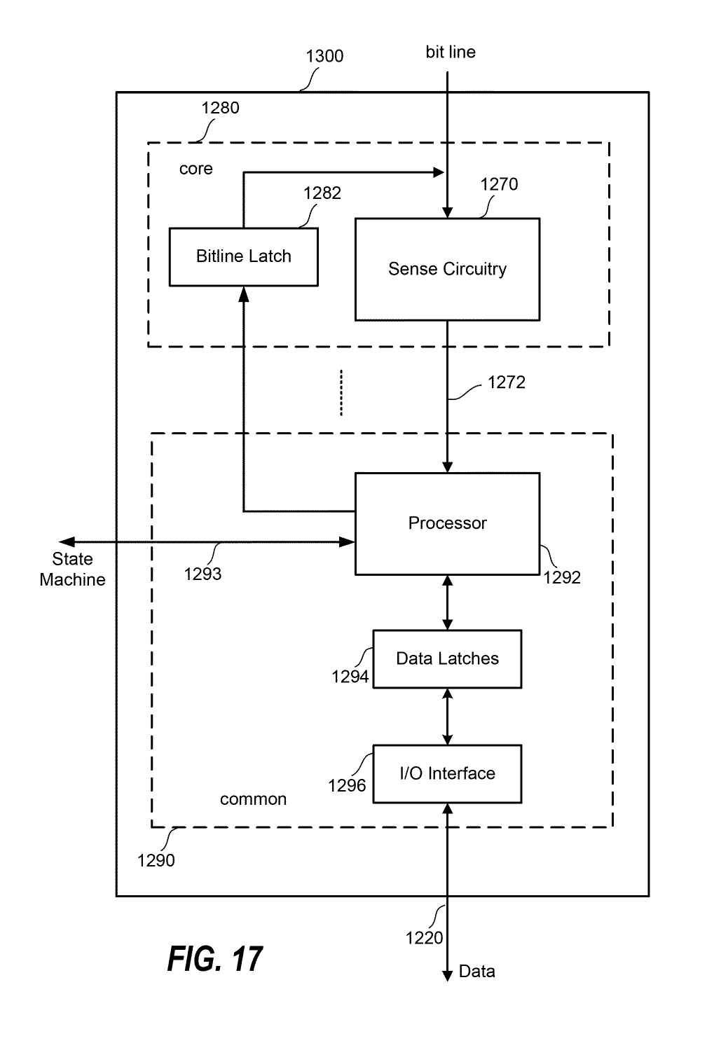

FIG. 17 is a block diagram of an individual sense block 1300 partitioned into a core portion, referred to as a sense module 1280, and a common portion 1290. In one embodiment, there will be a separate sense module 1280 for each bit line and one common portion 1290 for a set of multiple sense modules 1280. In one example, a sense block will include one common portion 1290 and eight sense modules 1280. Each of the sense modules in a group will communicate with the associated common portion via a data bus 1272. For further details, refer to U.S. Patent Application Publication 2006/0140007, which is incorporated herein by reference in its entirety.

Sense module 1280 comprises sense circuitry 1270 that determines whether a conduction current in a connected bit line is above or below a predetermined threshold level. In some embodiments, sense module 1280 includes a circuit commonly referred to as a sense amplifier. Sense module 1280 also includes a bit line latch 1282 that is used to set a voltage condition on the connected bit line. For example, a predetermined state latched in bit line latch 1282 will result in the connected bit line being pulled to a state designating program inhibit (e.g., Vdd).

Common portion 1290 comprises a processor 1292, a set of data latches 1294 and an I/O Interface 1296 coupled between the set of data latches 1294 and data bus 1220. Processor 1292 performs computations. For example, one of its functions is to determine the data stored in the sensed memory cell and store the determined data in the set of data latches. The set of data latches 1294 is used to store data bits determined by processor 1292 during a read operation. It is also used to store data bits imported from the data bus 1220 during a program operation. The imported data bits represent write data meant to be programmed into the memory. I/O interface 1296 provides an interface between data latches 1294 and the data bus 1220.

During read or sensing, the operation of the system is under the control of state machine 1022 that controls the supply of different control gate voltages to the addressed cell. As it steps through the various predefined control gate voltages corresponding to the various memory states supported by the memory, the sense module 1280 may trip at one of these voltages and an output will be provided from sense module 1280 to processor 1292 via bus 1272. At that point, processor 1292 determines the resultant memory state by consideration of the tripping event(s) of the sense module and the information about the applied control gate voltage from the state machine via input lines 1293. It then computes a binary encoding for the memory state and stores the resultant data bits into data latches 1294. In another embodiment of the core portion, bit line latch 1282 serves double duty, both as a latch for latching the output of the sense module 1280 and also as a bit line latch as described above.

It is anticipated that some implementations will include multiple processors 1292. In one embodiment, each processor 1292 will include an output line (not depicted in FIG. 12) such that each of the output lines is wired-OR'd together. In some embodiments, the output lines are inverted prior to being connected to the wired-OR line. This configuration enables a quick determination during the program verification process of when the programming process has completed because the state machine receiving the wired-OR line can determine when all bits being programmed have reached the desired level. For example, when each bit has reached its desired level, a logic zero for that bit will be sent to the wired-OR line (or a data one is inverted). When all bits output a data 0 (or a data one inverted), then the state machine knows to terminate the programming process. In embodiments where each processor communicates with eight sense modules, the state machine may (in some embodiments) need to read the wired-OR line eight times, or logic is added to processor 1292 to accumulate the results of the associated bit lines such that the state machine need only read the wired-OR line one time.

During program or verify, the data to be programmed is stored in the set of data latches 1294 from the data bus 1220. The program operation, under the control of the state machine, comprises a series of programming voltage pulses (with increasing magnitudes) applied to the control gates of the addressed memory cells. Each programming pulse is followed by a verify process to determine if the memory cell has been programmed to the desired state. Processor 1292 monitors the verified memory state relative to the desired memory state. When the two are in agreement, processor 1292 sets the bit line latch 1282 so as to cause the bit line to be pulled to a state designating program inhibit. This inhibits the cell coupled to the bit line from further programming even if it is subjected to programming pulses on its control gate. In other embodiments the processor initially loads the bit line latch 1282 and the sense circuitry sets it to an inhibit value during the verify process.

Data latch stack 1294 contains a stack of data latches corresponding to the sense module. In one embodiment, there are 3-5 (or another number) data latches per sense module 1280. In one embodiment, the latches are each one bit. In some implementations (but not required), the data latches are implemented as a shift register so that the parallel data stored therein is converted to serial data for data bus 1220, and vice versa. In one preferred embodiment, all the data latches corresponding to the read/write block of m memory cells can be linked together to form a block shift register so that a block of data can be input or output by serial transfer. In particular, the bank of read/write modules is adapted so that each of its set of data latches will shift data in to or out of the data bus in sequence as if they are part of a shift register for the entire read/write block.

Additional information about the read operations and sense amplifiers can be found in (1) U.S. Pat. No. 7,196,931, “Non-Volatile Memory And Method With Reduced Source Line Bias Errors,”; (2) U.S. Pat. No. 7,023,736, “Non-Volatile Memory And Method with Improved Sensing,”; (3) U.S. Patent Application Pub. No. 2005/0169082; (4) U.S. Pat. No. 7,196,928, “Compensating for Coupling During Read Operations of Non-Volatile Memory,” and (5) U.S. Patent Application Pub. No. 2006/0158947, “Reference Sense Amplifier For Non-Volatile Memory,” published on Jul. 20, 2006. All five of the immediately above-listed patent documents are incorporated herein by reference in their entirety.

Various features and techniques have been presented with respect to the NAND flash memory architecture. It will be appreciated from the provided disclosure that implementations of the disclosed technology are not so limited. By way of non-limiting example, embodiments in accordance with the present disclosure can provide and be used in the fabrication of a wide range of semiconductor devices, including but not limited to logic arrays, volatile memory arrays including SRAM and DRAM, and non-volatile memory arrays including both the NOR and NAND architecture.

A non-volatile memory array in one embodiment comprises a plurality of non-volatile storage elements arranged into rows and columns above a surface of a substrate and a plurality of isolation regions formed in the substrate between active areas of the substrate. The isolation regions extend through a cell area and select gate area of the substrate. A plurality of bit line air gaps are formed in the plurality of isolation regions. The bit line air gaps have a first vertical dimension at the cell area of the substrate and a second vertical dimension at the select gate area of the substrate, the second vertical dimension is less than the first vertical dimension.

A non-volatile memory array in one embodiment comprises a plurality of non-volatile storage elements arranged into rows and columns above a surface of a substrate and a plurality of isolation regions formed in the substrate between active areas of the substrate. The isolation regions extend through a cell area and a select gate area of the substrate. A plurality of bit line air gaps are formed in the plurality of isolation regions at the cell area of the substrate. A blocking material is formed in the plurality of isolation regions at a select gate area of the substrate.

A method of fabricating non-volatile storage in one embodiment comprises:

forming a first layer stack column and a second layer stack column elongated in a column direction over a substrate, each layer stack column having two vertical sidewalls and including a charge storage strip over a tunnel dielectric strip, the first layer stack column overlying a first active area of the substrate and the second layer stack column overlying a second active area of the substrate;

etching the substrate to define an isolation region between the first active area and the second active area, the isolation region extending through a cell area and a select gate area of the substrate; and

forming an air gap in the isolation region, the air gap having a first vertical dimension at the cell area of the substrate and a second vertical dimension at the select gate area of the substrate, the second vertical dimension is less than the first vertical dimension.

A method of fabricating non-volatile storage in one embodiment comprises:

forming a first layer stack column and a second layer stack column elongated in a column direction over a substrate, each layer stack column having two vertical sidewalls and including a charge storage strip over a tunnel dielectric strip, the first layer stack column overlying a first active area of the substrate and the second layer stack column overlying a second active area of the substrate;

etching the substrate to define an isolation region between the first active area and the second active area, the isolation region extending through a cell area and a select gate area of the substrate; and

forming an air gap in the isolation region, the air gap having a first vertical dimension at the cell area of the substrate and a second vertical dimension at the select gate area of the substrate, the second vertical dimension is less than the first vertical dimension.

A method of fabricating non-volatile storage in one embodiment comprises:

forming a first layer stack column and a second layer stack column elongated in a column direction over a substrate, each layer stack column having two vertical sidewalls and including a charge storage strip over a tunnel dielectric strip, the first layer stack column overlying a first active area of the substrate and the second layer stack column overlying a second active area of the substrate;

etching the substrate to define an isolation region between the first active area and the second active area, the isolation region extending through a cell area and a select gate area of the substrate;

forming an air gap in the isolation region at the cell area of the substrate; and

forming a blocking material in the isolation region at the select gate area of the substrate.

The foregoing detailed description has been presented for purposes of illustration and description. It is not intended to be exhaustive or to limit the subject matter claimed herein to the precise form(s) disclosed. Many modifications and variations are possible in light of the above teachings. The described embodiments were chosen in order to best explain the principles of the disclosed technology and its practical application to thereby enable others skilled in the art to best utilize the technology in various embodiments and with various modifications as are suited to the particular use contemplated. It is intended that the scope of the invention be defined by the claims appended hereto.

What is claimed is:

1. A non-volatile memory array, comprising:
a plurality of non-volatile storage elements arranged into rows and columns above a surface of a substrate;
a plurality of isolation regions formed in the substrate between active areas of the substrate, the isolation regions extending through a cell area and select gate area of the substrate; and
a plurality of bit line air gaps formed in the plurality of isolation regions, the bit line air gaps having a first vertical dimension at the cell area of the substrate and a second vertical dimension at the select gate area of the substrate, the second vertical dimension is less than the first vertical dimension.

2. A non-volatile memory according to claim 1, further comprising:
forming a first dielectric fill material in the plurality of isolation regions, the first dielectric fill material having an upper surface;
wherein the upper surface of the first dielectric fill material is a first distance from an upper surface of the substrate at the cell area and a second distance from the upper surface of the substrate at the select gate area, the second distance is less than the first distance;

3. A non-volatile memory according to claim 2, wherein:
the bit line air gaps have an upper endpoint a third distance above the substrate surface at the cell area and a fourth distance above the substrate surface at the select gate area, the third distance is less than the fourth distance.

4. A non-volatile memory according to claim 3, further comprising:
an intermediate dielectric layer formed into the rows of non-volatile storage elements;
the upper endpoint of the bit line air gaps is defined by a lower surface of the intermediate dielectric layer.

5. A non-volatile memory according to claim 4, further comprising:
a control gate layer formed into the rows of non-volatile storage elements above the intermediate dielectric layer.

6. A non-volatile memory according to claim 2, wherein:
the bit line air gaps have an upper endpoint a third distance above the substrate surface at the cell area and the select gate area.

7. A non-volatile memory according to claim 6, further comprising:
an intermediate dielectric layer formed into the rows of non-volatile storage elements;
a control gate layer formed into the rows of non-volatile storage elements above the intermediate dielectric layer.
wherein the upper endpoint of the bit line air gaps is defined by a lower surface of the intermediate dielectric layer.

8. A non-volatile memory array according to claim 1, further comprising:
a plurality of word line air gaps formed at least partially between adjacent rows of non-volatile storage elements.

9. A non-volatile memory array according to claim 1, wherein:
the columns of non-volatile storage elements are NAND strings including a plurality of non-volatile memory cells.

10. A non-volatile memory array, comprising:
a plurality of non-volatile storage elements arranged into rows and columns above a surface of a substrate;
a plurality of isolation regions formed in the substrate between active areas of the substrate, the isolation regions extending through a cell area and select gate area of the substrate; and
a plurality of bit line air gaps formed in the plurality of isolation regions at the cell area of the substrate; and
a blocking material formed in the plurality of isolation regions at a select gate area of the substrate.

11. A non-volatile memory array according to claim 10, wherein:
the blocking material includes a first dielectric layer and a second dielectric layer over the first dielectric layer, the second dielectric layer having a lower etch rate than the first dielectric layer.

12. A non-volatile memory array according to claim 11, further comprising:
a plurality of word line air gaps formed at least partially between adjacent rows of non-volatile storage elements.

13. A method of fabricating non-volatile storage, comprising:
forming a first layer stack column and a second layer stack column elongated in a column direction over a substrate, each layer stack column having two vertical sidewalls and including a charge storage strip over a tunnel dielectric strip, the first layer stack column overlying a first active area of the substrate and the second layer stack column overlying a second active area of the substrate;
etching the substrate to define an isolation region between the first active area and the second active area, the isolation region extending through a cell area and a select gate area of the substrate; and
forming an air gap in the isolation region, the air gap having a first vertical dimension at the cell area of the substrate and a second vertical dimension at the select gate area of the substrate, the second vertical dimension is less than the first vertical dimension.

14. A method according to claim 13, further comprising:
filling the isolation region with a first dielectric material having a first etch rate;
recessing the first dielectric material to define an upper surface of the first dielectric material below the substrate surface, the upper surface being a first distance below the substrate surface at the cell area and a second distance below the substrate surface at the select gate area, the second distance is less than the first distance.

15. A method according to claim 14, further comprising:
forming a sacrificial material in the isolation region over the first dielectric material;
forming an intermediate dielectric layer over the sacrificial material;
forming a control gate layer over the intermediate dielectric layer; and
etching the intermediate dielectric layer and the control gate layer into rows.

16. A method according to claim 15, further comprising:
removing the sacrificial material to from the air gap.

17. A method according to claim 16, wherein:
the air gap has an upper endpoint defined by a lower surface of the intermediate dielectric layer.

18. A method according to claim 17, wherein:
the lower surface of the intermediate dielectric layer is a third distance above the substrate surface at the cell area and a fourth distance above the substrate surface at the select gate area, the third distance is less than the fourth distance.

19. A method according to claim 17, wherein:
the lower surface of the intermediate dielectric layer is a third distance above the substrate surface at the cell area and the select gate area.

20. A method of fabricating non-volatile storage, comprising:
forming a first layer stack column and a second layer stack column elongated in a column direction over a substrate, each layer stack column having two vertical sidewalls and including a charge storage strip over a tunnel dielectric strip, the first layer stack column overlying a first active area of the substrate and the second layer stack column overlying a second active area of the substrate;
etching the substrate to define an isolation region between the first active area and the second active area, the isolation region extending through a cell area and a select gate area of the substrate;
forming an air gap in the isolation region at the cell area of the substrate; and
forming a blocking material in the isolation region at the select gate area of the substrate.

21. A method of fabricating non-volatile storage according to claim 20, wherein forming the blocking material comprises:
forming a first dielectric layer and a second dielectric layer over the first dielectric layer, the second dielectric layer having an etch rate that is less than an etch rate of the first dielectric layer.

22. A method of fabricating non-volatile storage according to claim 21, further comprising:
removing the first dielectric layer at the cell area while leaving the first dielectric layer at the select gate area to form the air gap at the cell area.
